(19) United States
(12) Patent Application Publication
(10) Pub. No.: US 2026/0096074 A1
(43) Pub. Date: Apr. 2, 2026

(54) POWER ELECTRONICS UNIT FOR A VEHICLE

(71) Applicant: ZF Friedrichshafen AG, Friedrichshafen (DE)

(72) Inventors: Illia Manushyn, Pegnitz (DE); Claudio Pero, Ravensburg (DE); Thomas Spangler, Neumarkt i. d. OPf. (DE); Armin Walter, Dingolshausen (DE); Andreas Schakies, Nürnberg (DE); Matthias Scheidel, Abenberg (DE); Friedrich Bach, Lauf a. d. Pegnitz (DE); Jens Bachstein, Salem (DE)

(73) Assignee: ZF Friedrichshafen AG, Friedrichshafen (DE)

(21) Appl. No.: 19/346,783

(22) Filed: Oct. 1, 2025

(30) Foreign Application Priority Data
Oct. 1, 2024 (DE) 10 2024 209 573.7

(51) Int. Cl. H05K 9/00; B60L 50/60; H05K 7/14

(52) U.S. Cl. CPC H05K 9/0022; B60L 50/60; H05K 7/1432

(57) ABSTRACT

A power electronics unit for a vehicle, comprising: a housing; a boundary, which divides the housing into an interference reduction area and an interference source area, and separates the interference reduction area from the interference source area; high-voltage power electronics inside the interference source area; and a printed circuit board, at least part of which is inside the interference reduction area, wherein there is a low-voltage connection for low-voltage signals in the interference reduction area, wherein the low-voltage signals are sent to and from a higher-order system in the vehicle, and wherein there is a battery connection to the power electronics unit on the printed circuit board inside the interference reduction area. The present disclosure also relates to a vehicle that has a battery, and electric motor, and a power electronics unit.

### CROSS-REFERENCE TO RELATED APPLICATION

This application claims priority to German Patent Application No. 10 2024 209 573.7 filed on Oct. 1, 2024, the entirety of which is hereby fully incorporated by reference herein.

### TECHNICAL FIELD

The present disclosure relates to a power electronics unit for a vehicle. The present disclosure also relates to a vehicle with a power electronics unit.

### BACKGROUND

There are both purely electric vehicles and hybrid vehicles in the prior art that are powered either entirely or in part by one or more electric machines. These vehicles contain electric energy storage units, preferably in the form of rechargeable batteries, which provide the necessary electricity for the electric machines. These batteries are normally direct current sources, while the electric machines require alternating current. For this reason, there are normally power electronics units such as converters between the batteries and the electric machines in electric and hybrid vehicles, for the necessary electricity conversion.

The power electronics units normally contain high voltage power electronics with numerous semiconductor switches. These semiconductor switches are transistors, e.g. MOSFETs or IGBTs, which are normally in half bridge circuits. High-frequency switching takes place when the power electronics units are in use to generate numerous temporally offset phase currents in an alternating current (AC) from a direct current (DC) applied to the half bridges.

The high-frequency switching in the power electronics units results in electromagnetic interference (EMI). This EMI can be problematic, as it may disrupt the functioning of the electronic components. It also has a negative impact on electromagnetic compatibility (EMV), which plays an important role in ensuring that the vehicle functions safely.

An electric drive system for an electric vehicle is described in DE 2020 14 101 689 U1. The drive system has a housing that is subdivided into numerous spaces on the inside. The drive system also contains numerous power converters in the separate spaces. It also contains connecting bars formed on the surface of the housing, which connect the power converters to a battery. It also contains adapters that connect the connecting bars to the power converters, each of which has an inner surface and an outer surface. The inner surface of the adapter is populated with conductors that are connected to electrodes in the power converters when the electrodes are placed therein. The outer surface is populated with shielding elements that cover the conductors to shield them from noises generated by the power converters. Each of the power converters contains a high-voltage switching unit and a low-voltage switching unit. The high-voltage switching unit and low-voltage switching unit are covered by shields and spaced apart within each space.

It may be difficult to reduce electromagnetic interference in electric vehicles, because the EMI frequently occurs at the power source for the power electronics units. This interference cannot be entirely eliminated with conventional methods. This is why shielded wires are needed. These shielded wires ensure the electromagnetic compatibility according to the mandatory norms, as well as the functioning and safety of the vehicle.

The disadvantage with prior approaches is that the shielded wires are relatively expensive. This significantly increases costs, due to the expensive materials and specialized shielding technologies. This also increases the size of the electrical system, making it more difficult to incorporate in compact vehicle designs. The additional material also increases the weight, which is a problem with electric vehicles in particular. Furthermore, negative interactions between inverter modules may be reduced, improving the immunity of the inverter.

### SUMMARY

Based on the foregoing, an object of the present disclosure is to create an effective way of reducing electromagnetic interference in power electronics units.

To solve this problem, one aspect of the present disclosure relates to a power electronics unit for a vehicle that comprises:
a housing;
a boundary that divides the housing into an interference reducing area and an interference source area, which separates these areas electromagnetically;
high-voltage power electronics inside the interference source area; and
a printed circuit board, at least part of which is inside the interference reducing area where it has a low-voltage connection for low-voltage signals, which are sent to and from a higher order system in the vehicle, which also has a battery connection for the power electronics unit.

Another aspect of the present disclosure relates to a vehicle that has an electric motor, a battery, and a power electronics unit such as that described above, in which
the high-voltage power electronics in the power electronics unit contain at least one commutation cell and busbars for connecting the commutation cells to the power source; and
the battery connection in the power electronics unit is connected to the vehicle battery by unshielded wires.

Various embodiments of the present disclosure are described herein. It is understood that the features specified above and described below can be used not only in the given combinations, but also in other combinations or in and of themselves, without abandoning the scope of the present disclosure.

The present disclosure relates to a power electronics unit for a vehicle. The power electronics unit has a housing for this. It also has a boundary that divides the housing into an interference reduction area and an interference source area, thus electromagnetically separating the two areas from one another. The power electronics unit also contains high-voltage power electronics within the interference source area. The power electronics unit also contains a printed circuit board, at least part of which is inside the interference reduction area. There is a low-voltage connection on the printed circuit board inside the interference reduction area for low-voltage signals that are sent to and from a higher-order system in the vehicle. There is a battery connection on the printed circuit board inside the interference reduction area with which the power electronics unit is supplied with electricity. In particular, all of the power outputs to the vehicle and battery are inside the interference reduction area. The printed circuit board can also be subdivided into numerous individual printed circuit boards.

The high-voltage power electronics are in the interference source area of the power electronics unit, and designed to work with high-voltage signals, in particular alternating currents. The components in the high-voltage power electronics generate electromagnetic fields that may disrupt other electronic systems, thus forming interference sources. These interference sources include semiconductor switches, e.g. MOSFETs and IGBTs, in half bridge circuits, intermediate circuit capacitors, power modules that process higher currents and voltages, and commutation cells and DC/DC converters. These components generate disruptive electromagnetic fields with their high power densities and steep signal edges.

The power electronics unit is advantageously divided by the boundary into an interference reduction area and an interference source area, thus separating the two areas electromagnetically. This separation protects the sensitive low-voltage components in the interference reduction area from the electromagnetic interferences emitted by the high-voltage power electronics in the interference source area. This results in greater reliability and stability of the low-voltage signals necessary for communicating with the high-order vehicle system.

In an example design, the boundary is formed by an electrically conductive shield. This shield is between the interference source area and the interference reduction area and forms an effective and inexpensive barrier. This boundary can also contain optical couplers, filters, inductive components, separating grooves on the printed circuit board, shielding vias on the printed circuit board, and/or galvanic spacers.

In an example design, the printed circuit board has a ground surface connected by at least one decoupling capacitor to the shield. This ground surface forms an additional shield, thus improving the electromagnetic separation. The use of decoupling capacitors ensures that high-frequency interference can be diverted to the ground or chassis, protecting the integrity of the low-voltage signals on the printed circuit board.

In an example design, the ground surface faces the shield. This results in supplementary shielding by one of the elements on the printed circuit board. This reduces the electromagnetic coupling between the printed circuit board and the interference sources.

In an example design, the low-voltage connection and the battery connection are isolated on the printed circuit board inside a connecting sector. The term, “isolated,” indicates in this example design that the plug-in connecting sector is spatially separated from other components on the printed circuit board. This isolation thus contributes to improving the electromagnetic separation.

In an example design, the boundary on the printed circuit board comprises filters for reducing common-mode interference and/or differential-mode interference in the power supply for the high-voltage power electronics. Because the power supply is connected to the high-voltage power electronics, it is particularly vulnerable to electromagnetic interference. The filters effectively reduce this interference, directly improving the power supply to the power electronics unit. This increases the electromagnetic compatibility and the reliability of the entire power electronics unit.

In an example design, the high-voltage power electronics contain switches, in particular semiconductor switches and/or intermediate circuit capacitors, and/or inductive components, in particular transformers. These high-voltage power electronics advantageously result in an efficient and reliable electricity conversion as a result of the use of these switching components.

In an example design, the printed circuit board has output signal conductors for the power supply for the high-voltage power electronics. This printed circuit board also has low-voltage conductors for the low voltage signals. The boundary also has separating grooves on the printed circuit board for separating the output signal conductors from the low-voltage conductors, and/or shielding elements on the printed circuit board for shielding the output signal conductors from the low-voltage conductors. The advantage with this is that the grooves and shielding elements on the printed circuit board effectively separate and shield the high-voltage output signal conductors from the low-voltage conductors. This reduces electromagnetic interference between the high and low-voltage signals, improves the signal integrity, and increases the reliability of the entire power electronics unit.

In an example design, the shield and/or housing are made of sheet metal, in particular copper or aluminum sheet metal, amorphous metal, and/or plated metal. These materials are electrically conductive, and thus form an effective shield against electromagnetic interference. A Faraday cage can therefore be formed that entirely encompasses the interference source area. This improves the electromagnetic compatibility of the entire power electronics unit and increases the reliability of the electronic components in the vehicle.

In an example design, the battery connection and low-voltage connection each have a plug-in connector. This simplifies the installation and replacement of the power electronics unit, because the connections can be obtained quickly and reliably. Plug-in connectors also ensure a robust and reliable electrical connection, which is necessary for transmitting high-voltage and low-voltage signals.

In an example design, the boundary contains numerous shields inside the housing that divides the housing into numerous interference source areas and interference reduction areas, in which each shield is designed to electromagnetically separate the respective interference source areas from the interference reduction areas. Consequently, numerous interference source areas, containing various high-voltage power electronics components, and interference reduction areas can be formed and effectively shielded within the same power electronics unit. This allows for a flexible configuration of the electronic components and improves the electromagnetic compatibility of the entire power electronics unit.

In an example design, the printed circuit board is modular and can be mechanically and/or electrically releasably attached to the shield, in particular with a snap-in, plug-in, or threaded connection. The modular structure makes it possible to adjust the printed circuit board to the needs of the power electronics unit. This increases production flexibility because components can be easily added, removed, or exchanged, without having to replace the entire power electronics unit.

The present disclosure also relates to a vehicle with an electric motor and a power electronics unit as described above, in which the high-voltage power electronics in the power electronics unit contains at least one commutation cell and busbars for supplying electricity to the commutation cell, and the battery connection in the power electronics unit is connected to the vehicle battery by unshielded wires.

The vehicle obtained with the present disclosure also has the advantages described with regard to the power electronics unit obtained according to the present disclosure.

It is also advantageous that the high-voltage power electronics in the power electronics unit result in an efficient power supply as a result of the integration of commutation cells and busbars. This allows for a conversion of the high voltage for operating the electric motor.

Another advantage is that the power electronics unit isolates all critical electromagnetic interference within the housing with its effecting shielding. This allows for the use of unshielded wires for connecting the battery connection to the battery. This simplifies the wiring and reduces material and production costs. The electromagnetic compatibility still remains intact, because the internal shielding in the power electronics unit effectively prevents electromagnetic interference through the wiring impacting other electronic systems in the vehicle. This results in a more robust and cost-effective system architecture.

The present disclosure shall be described and explained below in greater detail based on the selected exemplary embodiments in the drawings.

### BRIEF DESCRIPTION OF THE DRAWINGS

FIG. 1 shows a schematic, simplified side view of a vehicle obtained with the present disclosure, which has a power electronics unit and an electric motor;

FIG. 2 shows a schematic illustration of a first exemplary embodiment of the power electronics unit obtained with the present disclosure;

FIG. 3a shows a schematic illustration of the division of a second exemplary embodiment of the power electronics unit obtained with the present disclosure; and

FIG. 3b shows a schematic illustration of the division of a third exemplary embodiment of the power electronics unit obtained with the present disclosure.

### DETAILED DESCRIPTION

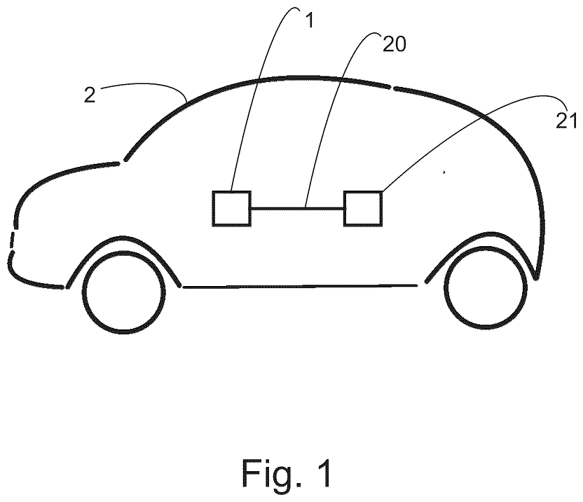

FIG. 1 shows a schematic, simplified side view of the vehicle 2 obtained with the present disclosure with a power electronics unit 1, a battery 21, and an electric motor (not shown). The power electronics unit 1 contains a battery connection connected to the battery 21 in the vehicle 2 by an unshielded wire 20.

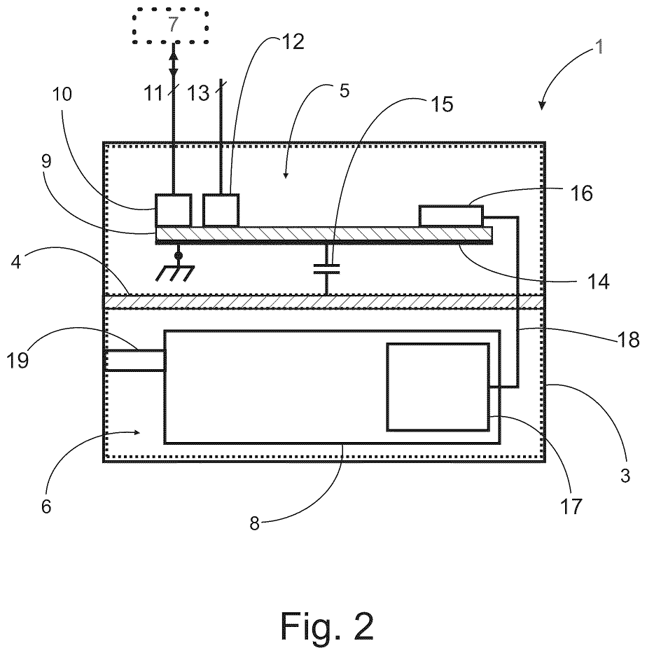

FIG. 2 shows a schematic illustration of a first exemplary embodiment of the power electronics unit 1 obtained with the present disclosure. The power electronics unit 1 in this exemplary embodiment has an electrically conductive housing 3 made of aluminum. The shield 4 divides the housing 3 into an interference reduction area 5 and an interference source area 6.

In this exemplary embodiment, the shield 4 comprises electrically conductive sheet metal. The shape of the shield can be adapted to the shape of the housing 3. Reinforcements can be used to stiffen the shield.

The interference source area 6 contains high-voltage power electronics 8 with a commutation cell 17 and components that are primarily responsible for generating electromagnetic interference. These include power semiconductors (specifically transistors and/or diodes) in particular. The high-voltage power electronics 8 are connected directly or indirectly, via high-voltage wires, to the electric motor in the vehicle 2 in order to supply it with alternating current. These components are inside the interference source area 6 such that their electromagnetic emissions are shielded. The commutation cells 17 are supplied with electricity by busbars 19, which are also inside the interference source area 6. There can also be an additional filter (not shown) in this area.

The interference reduction area 5 contains sensitive electronic components that could be disrupted by the electromagnetic interferences. These include control electronics for the high-voltage power electronics 8 with dedicated signal conductors.

By dividing the power electronics unit 1 into these two defined areas with the boundary 4, electromagnetic interference is effectively reduced. The housing 3 (made of aluminum, for example) provides not only mechanical stability, but also shields against electromagnetic radiation. The boundary 4 and housing 3 therefore electromagnetically separate the interference reduction area 5 from the interference source area 6.

The exemplary embodiment also contains a printed circuit board 9, which is entirely inside the interference reduction area 5. The printed circuit board 9 has a grounded ground surface 14 on the bottom.

The ground surface 14 on the printed circuit board 9 is a continuous copper layer that forms a return path for electrical signals. It helps in reducing electromagnetic interference by functioning as an additional shield. The ground surface 14 faces the shield 4 and is connected thereto by a decoupling capacitor 15.

There is a low-voltage connection 10 for low-voltage signals 11 on the printed circuit board 9. The low-voltage signals 11 come from a higher-order vehicle system 7, e.g. the electrical system for the vehicle, and include control signals and measurement signals in particular. The low-voltage signals 11 are used to control the components in the high-voltage power electronics 8. The higher-order vehicle system 7 also receives low-voltage signals 11 from the power electronics unit 1. The low-voltage signals 11 in this exemplary embodiment range from 0 to 24 volts. The shielding of the signal conductor can be reduced or entirely eliminated with the present disclosure.

There is also a battery connection 12 on the printed circuit board 9 for an input power connection 13 for the power electronics unit 1. The voltage in this exemplary embodiment ranges from 60 to 800 volts.

The boundary 4 in this exemplary embodiment contains a filter 16 on the printed circuit board 9 that reduces common-mode interference and/or differential-mode interference in the power supply 18 for the high-voltage power electronics 8.

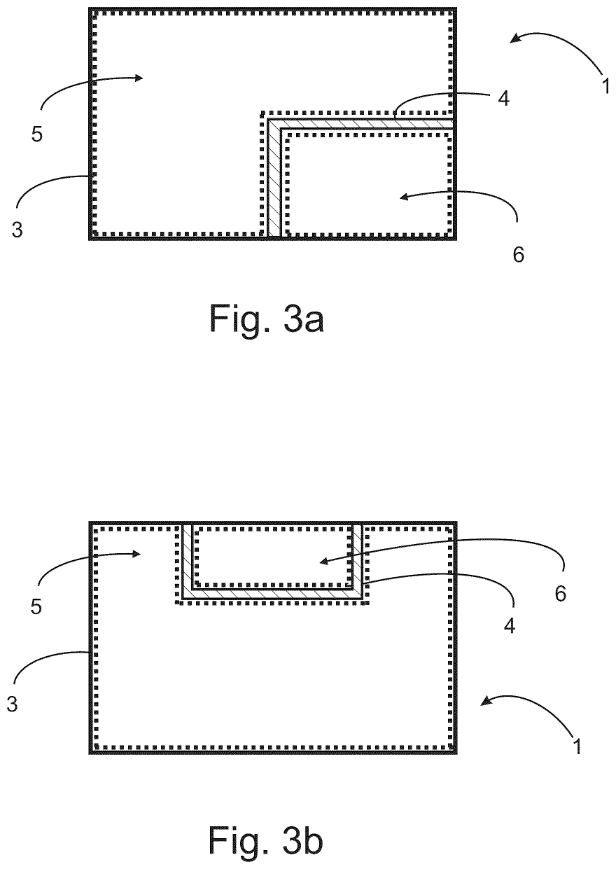

FIG. 3a shows a schematic illustration of how a second exemplary embodiment of the power electronics unit 1 is divided up. In this exemplary embodiment, the power electronics unit 1 has an electrically conductive housing 3. The boundary 4 therein has an electrically conductive rectangular shield. This boundary 4 divides the housing 3 into an interference reduction area 5 and an interference source area 6.

In another embodiment, these areas 5, 6 are reversed.

FIG. 3b shows a schematic illustration of the division of a third exemplary embodiment of the power electronics unit 1 obtained with the present disclosure. In this exemplary embodiment, the power electronics unit 1 has an electrically conductive housing 3 and a boundary 4 that has an electrically conductive shield. The shield, which is U-shaped, divides the housing 3 into an interference reduction area 5 and an interference source area 6.

In another embodiment, these areas 5, 6 are reversed.

The present disclosure has been comprehensively described and explained in reference to the drawings. These explanations are to be regarded as exemplary, and not limiting. The present disclosure is not limited to the disclosed embodiments. Other embodiments or variations can be derived by the person skilled in the art when using the present disclosure and through a precise analysis of the drawings, the disclosure, and the following claims.

In the claims, the words, “comprise,” and “with” do not exclude the presence of other elements or steps. The indefinite articles, “a” or “an” do not exclude pluralities. A single element or unit can execute the functions of numerous units specified in the claims. Simply specifying certain measures in numerous dependent claims is not to be understood to mean that a combination of these measures cannot also be used advantageously. Reference symbols in the claims are not limiting.

### REFERENCE SYMBOLS

1 power electronics unit
2 vehicle
3 housing
4 boundary
5 interference reduction area
6 interference source area
7 higher-order vehicle system
8 high-voltage power electronics
9 printed circuit board
10 low-voltage connection
11 low-voltage signals
12 battery connection
13 power supply for the power electronics unit
14 ground surface
15 decoupling capacitor
16 filter
17 commutation cell
18 power supply for the high-voltage power electronics
19 busbars
20 wire
21 battery

1. A power electronics unit for a vehicle, comprising:
a housing;
a boundary, which divides the housing into an interference reduction area and an interference source area, and separates the interference reduction area from the interference source area;
high-voltage power electronics inside the interference source area; and
a printed circuit board, at least part of which is inside the interference reduction area, wherein there is a low-voltage connection for low-voltage signals in the interference reduction area, wherein the low-voltage signals are sent to and from a higher-order system in the vehicle, and wherein there is a battery connection to the power electronics unit on the printed circuit board inside the interference reduction area.

2. The power electronics unit according to claim 1,
wherein the boundary comprises an electrically conductive shielding plate.

3. The power electronics unit according to claim 2,
wherein the printed circuit board has a ground surface that is connected by at least one decoupling capacitor to the shielding plate and faces the shielding shield.

4. The power electronics unit according to claim 1,
wherein the low-voltage connection and battery connection are isolated inside a connecting sector on the printed circuit board.

5. The power electronics unit according to claim 1,
wherein the boundary comprises filters on the printed circuit board configured to reduce common-mode interference and/or differential-mode interference in a power supply for the high-voltage power electronics.

6. The power electronics unit according to claim 1,
wherein the high-voltage power electronics contain semiconductor switches and/or intermediate circuit capacitors, and/or inductive components comprising transformers.

7. The power electronics unit according to claim 1,
wherein the printed circuit board has output signal conductors for a power supply for the high-voltage power electronics, and low-voltage conductors for the low-voltage signals, and wherein the boundary comprises separating grooves on the printed circuit board configured to separate the output signal conductors from the low-voltage conductors and/or shielding elements on the printed circuit board for shielding the output signal conductor from the low-voltage conductors.

8. The power electronics unit according to claim 2,
wherein the shielding plate and/or the housing are made of sheet metal comprising copper or aluminum, or amorphous metal, and/or plated metal.

9. The power electronics unit according to claim 1,
wherein the battery connection and the low-voltage connection each have a plug-in connector.

10. A vehicle comprising:
a battery;
an electric motor; and
a power electronics unit according to claim 1, wherein the high-voltage power electronics in the power electronics unit contain at least one commutation cell and busbars configured to supply power to the commutation cells, and wherein the battery connection in the power electronics unit is connected to the battery in the vehicle by unshielded wire.
